(19) United States
(12) Patent Application Publication
(10) Pub. No.: US 2021/0098651 A1
(43) Pub. Date: Apr. 1, 2021

(54) SILICON-BASED DIRECT BANDGAP LIGHT-EMITTING MATERIAL AND PREPARATION METHOD THEREOF, AND ON-CHIP LIGHT-EMITTING DEVICE

(71) Applicant: Institute of Semiconductors, Chinese Academy of Sciences, Beijing (CN)

(72) Inventors: Junwei Luo, Beijing (CN); Linding Yuan, Beijing (CN); Shushen Li, Beijing (CN)

(21) Appl. No.: 16/760,863

(22) PCT Filed: Mar. 12, 2018
(86) PCT No.: PCT/CN2018/078711

§ 371 Date: Apr. 30, 2020

(51) Int. Cl. H01L 33/34; H01L 33/00; H01L 33/18; H01L 33/02

(52) U.S. Cl. CPC H01L 33/343; H01L 33/0054; H01L 33/025; H01L 33/0095; H01L 33/18

(57) ABSTRACT

The present disclosure provides a silicon-based direct band gap light-emitting material compatible with the CMOS fabrication process, and a preparation method thereof. The method comprises steps of: preparing a silicon-based material, wherein the silicon-based material is a germanium material or a silicon-germanium alloy; filling some of lattice interstitial sites of the silicon-based material with noble gas atoms and/or other atoms with a low atomic number, so as to expand the lattice volume in order to transform the band structure from indirect band gap to direct band gap, thereby obtaining a silicon-based direct band gap light-emitting material. The present disclosure also provides a silicon-based light-emitting device. The preparation method of the present disclosure is compatible with CMOS integrated circuit processes, and realizes direct band gap light-emission from germanium and silicon germanium alloy materials with a light-emitting efficiency comparable to that of direct band gap Group III-V materials such as InP and GaAs, thus offering a completely new solution for on-chip light sources required for silicon- or germanium-based optoelectronic integration technologies.

### CROSS-REFERENCE TO RELATED APPLICATION

This application is a U.S. National Stage Application under 35 U.S.C. § 371 of International Application No. PCT/CN2018/078711, filed on Mar. 12, 2018, the disclosure of which is incorporated herein by reference in its entirety.

### TECHNICAL FIELD

The present disclosure relates to the field of semiconductor technology, and particularly relates to a silicon-based direct band gap light-emitting material compatible with the microelectronic CMOS fabrication process, a preparation method thereof, and a silicon-based light-emitting device.

### BACKGROUND

Microelectronics technology is the cornerstone of the current information industry. However, it is difficult to integrate highly-efficient light-emitting devices on microelectronic chips.

### SUMMARY

In one aspect of the present disclosure, a method for preparing a silicon-based direct band gap light-emitting material in compatible with the CMOS fabrication process is provided, comprising steps of:

S1. preparing a silicon-based material, wherein the silicon-based material is a germanium material or a silicon-germanium alloy;

S2. filling some of lattice interstitial sites of the silicon-based material with noble gas atoms and/or other atoms with a low atomic number, so as to cause the lattice expansion for transforming an energy band structure of the silicon-based material from an indirect band gap to a direct band gap, thereby obtaining a silicon-based direct band gap light-emitting material.

In some embodiments of the present disclosure, the step of filling is implemented by ion implantation, electrochemical implantation, and epitaxial growth.

In some embodiments of the present disclosure, a concentration of silicon in the silicon-germanium alloy is no more than 50%.

In another aspect of the present disclosure, a silicon-based light-emitting material is also provided. The silicon-based light-emitting material is a germanium material or a silicon-germanium alloy having an energy band structure of a direct band gap, wherein some of lattice interstitial sites thereof are filled with noble gas atoms and/or other atoms with a low atomic number.

In some embodiments of the present disclosure, the silicon-based light-emitting material is a crystalline structure characterized in having a regular tetrahedral bonding.

In some embodiments of the present disclosure, the crystalline structure characterized in having the regular tetrahedral bonding is a diamond or diamond-like structure or a biaxially strained diamond structure.

In some embodiments of the present disclosure, the silicon-based material is a bulk material, a thin film material, or a micro/nano structure material.

In some embodiments of the present disclosure, the noble gas atoms are helium atoms with a concentration of 9.0% or more relative to the germanium or silicon plus germanium (for silicon-germanium alloy) atoms; and/or

the noble gas atoms are neon atoms with a concentration of 1.5% or more relative to the germanium or silicon plus germanium (for silicon-germanium alloy) atoms; and/or

the noble gas atoms are argon atoms with a concentration of 0.8% or more relative to the germanium or silicon plus germanium (for silicon-germanium alloy) atoms; and/or

the noble gas atoms are krypton atoms with a concentration of 0.8% or more relative to the germanium or silicon plus germanium (for silicon-germanium alloy) atoms.

In some embodiments of the present disclosure, the other atoms with a low atomic number comprise lithium atoms with a concentration of 3.0% or more relative to the germanium or silicon plus germanium (for silicon-germanium alloy) atoms.

In another aspect of the present disclosure, there is further provided a silicon-based light-emitting device, comprising:

a microelectronic chip, comprising a silicon microelectronic chip or a germanium microelectronic chip;

a silicon-germanium alloy buffer layer, deposited on the silicon microelectronic chip;

a germanium substrate, deposited on the silicon-germanium alloy buffer layer; and

a silicon-based light-emitting material, deposited on the germanium substrate or on the germanium microelectronic chip, the silicon-based light-emitting material being a germanium material or a silicon-germanium alloy having an energy band structure of a direct band gap, wherein some of lattice interstitial sites thereof are filled with noble gas atoms and/or other atoms with a low atomic number.

Compared with the existing Group III-V light-emitting materials integrated on a microelectronic chip by using a hybrid integration technology, the silicon-based light-emitting material (germanium or silicon-germanium alloy material) of the present disclosure can achieve a high-quality monolithically epitaxial growth on a microelectronic chip. It is perfectly compatible with existing CMOS fabrication process without the problem of thermal mismatch, and can be used to produce large-scale integrated light sources (silicon-based light-emitting devices) on microelectronic chips.

Compared with the existing tin-germanium alloy, the silicon-based light-emitting material (germanium or silicon-germanium alloy material) of the present disclosure can avoid lattice defects caused by extremely large lattice mismatch between tin and germanium and be resistant to harmful impurities that may affect the light-emission efficiency, since the interstitial atoms filled in the lattices of germanium or silicon-germanium alloy have a small size, and are required in a low interstitial concentration.

Compared with the existing method of achieving a direct band gap light-emission of germanium by generating tensile strain via a micromechanical method, the present disclosure fills some of interstitial sites of germanium or silicon-germanium alloy lattices with noble gas atoms and/or other atoms with a low atomic number, such as lithium atoms, to enable a lattice volume expansion, which may equivalently generate the tensile strain required for achieving a direct band gap light emission from germanium or silicon-germanium alloy. The present disclosure may solve the problem that the micromechanical method cannot be applied for large-scale integration on chip. This method is compatible with existing silicon CMOS fabrication process and can be used to fabricate large-scale integrated light sources on a microelectronics chip.

With different types of atoms to be filled with and different atom concentration, the silicon-based light-emitting material of the present disclosure may have different values in band gap, and corresponding radiative lifetimes of the band edge transitions of excitons are also varying. Thus, the wavelength of the emitted photons can be tuned in a certain range of far-infrared waveband, thereby obtaining light-emitting germanium or silicon-germanium alloy materials with different effects, so as to meet actual needs.

### BRIEF DESCRIPTION OF THE ACCOMPANYING DRAWINGS

FIG. 1 shows a flowchart of steps in a method for preparing a silicon-based light-emitting material according to an embodiment of the present disclosure;

FIG. 2A shows a schematic structural diagram of a silicon-based light-emitting device according to a first embodiment of the present disclosure;

FIG. 2B shows a schematic structural diagram of a silicon-based light-emitting device according to a second embodiment of the present disclosure;

FIG. 3 shows a schematic diagram of a germanium crystalline structure (Ge₃₂Li₁) with a lithium atom concentration of 3.0% according to an embodiment of the present disclosure;

FIG. 4 shows a schematic diagram of a germanium crystalline structure (Ge₃₂Li₂) with a lithium atom concentration of 6.0% according to an embodiment of the present disclosure;

FIG. 5 shows a schematic diagram of the energy band structure of the germanium crystalline structure (Ge₃₂Li₁) with a lithium atom concentration of 3.0% and the germanium crystalline structure (Ge₃₂Li₂) with a lithium atom concentration of 6.0%, by projecting k-components of electronic states onto the FCC Brillouin zone of a pure germanium, according to an embodiment of the present disclosure.

FIG. 6 shows a schematic diagram illustrating relationships of the direct band gap, indirect band gap, and matrix element of the band-edge transition versus the interstitial atom concentration for the germanium material, epitaxially grown on the germanium substrate, with some lattice interstitial sites filled by lithium atoms according to an embodiment of the present disclosure;

FIG. 7 shows a schematic diagram illustrating relationships of the direct band gap, indirect band gap, and matrix element of the band-edge transition versus the interstitial atom concentration for the germanium material, epitaxially grown on the germanium substrate, with some lattice interstitial sites filled by helium atoms according to an embodiment of the present disclosure;

FIG. 8 shows a schematic diagram illustrating relationships of the direct band gap, indirect band gap, and the matrix elements of the band-edge transition versus the interstitial atom concentration for the germanium material, epitaxially grown on the germanium substrate, with some lattice interstitial sites filled by neon atoms according to an embodiment of the present disclosure;

FIG. 9 shows a schematic diagram illustrating relationships of the direct band gap, indirect band gap, and the matrix element of the band-edge transition versus the interstitial atom concentration for the germanium material, epitaxially grown on the germanium substrate, with some lattice interstitial sites filled by argon atoms according to an embodiment of the present disclosure;

FIG. 10 shows a schematic diagram illustrating relationships of the direct band gap, indirect band gap, and the matrix element of the band-edge transition versus the interstitial atom concentration for the germanium material, epitaxially grown on the germanium substrate, with some lattice interstitial sites filled by krypton atoms according to an embodiment of the present disclosure.

### DETAILED DESCRIPTION

Microelectronics is currently the cornerstone of the information technologies. In the past half century, the development of the microelectronics technology has followed the Moore's Law that the number of transistors incorporated on a microchip doubles roughly every 18 months due to shrinking transistor dimensions. As transistor scaling approaches the physical limits, Moore's Law reaches about a dead end. The optoelectronic integrated circuit (OEIC) technology for integrating both electronic devices and photonics devices on a single microchip is becoming increasingly mature, and is expected to take over microelectronics as the cornerstone of the information technologies in the near future. The main challenge of silicon-based OEIC is to integrate photonic components including light sources, photodetectors, optical waveguides, and light modulators on microelectronic chips fabricated using the existing silicon infrastructure. OEIC uses optical interconnections instead of metal interconnections to provide much higher data transmission capabilities, thereby breaking the physical limits of metal interconnections, significantly reducing system power consumption, and solving the problem of the integration degree being limited by heat generation. OEIC could also enable unprecedented functions and performance in computing and sensing. However, silicon and germanium (compatible with Si) are both indirect band gap materials that do not emit light efficiently and limit their usage in on-chip light sources. Currently, failure to fabricate on-chip light sources in a way compatible with silicon-based CMOS (Complementary Metal Oxide Semiconductor) process has become the primary challenge hindering the development of silicon-based OEIC technology. Therefore, finding a high-efficient light-emitting material compatible with CMOS process is the key towards silicon-based optoelectronic integration technology.

For more than half a century, researchers have been looking for silicon-based high-efficiency light-emitting materials, and proposed many different methods and solutions to achieve on-chip light-emitter. There are new research results reported in top international journals every year. But so far, no applicable on-chip light sources have been successfully developed. One of proposed schemes is relying on high-efficiency radiative emission from rare-earth (such as europium) doped silicon materials. However, room-temperature Rare-Earth-Doped laser suffers from poor current injection as well as low solid solubility, uniform distribution, and low optical activity of rare-earth ions in monocrystal silicon. Tremendous efforts have also been made to study porous silicon, silicon-germanium alloy, germanium-tin alloy, silicon isomorphs, silicon quantum dots, silicon-silica superlattices, silicon-germanium superlattices, III-V semiconductors on silicon and the like which are expected to achieve silicon-based high-efficiency light-emission. However, none of these candidates has been used to make practically applicable light source that can be integrated on a silicon microchip.

In addition, considering that the energy level of the direct band gap is only 0.15 eV higher than the fundamental indirect band gap in germanium, researchers have found that a small magnitude of tensile strain applied to the crystalline germanium or its low-dimensional micro/nano structure could transfer its band gap from indirect to direct, thus satisfying the requirements for efficient light emission. Currently, in the laboratory, such extensile strain has been applied, with limited success, to germaniums using micromechanical engineering technologies, such as using high-pressure gas to stretch the mounted germanium nanomembranes, causing sufficient tensile strain at the outside of the bent apex, and making germanium nanomembranes direct band gap light emission. Such tensile strain can also be provided by epitaxially growing germanium on a substrate with larger lattice. However, in the silicon CMOS structure, it is impossible to provide the substrate with a larger lattice constant than germanium and to use micromechanical approaches to apply sufficient tensile strain to germanium for fabrication of very large-scale integration on a microchip. In summary, the solution of achieving highly-efficient light emission of germanium by simply applying tensile stress cannot currently solve the problem of integrating high-efficiency light-emitting devices on microelectronic chips.

In view of shortcomings of the prior art described above, the present disclosure provides a silicon-based direct band gap light-emitting material (germanium or silicon-germanium alloy) compatible with existing CMOS fabrication process and a preparation method thereof, so as to obtain a silicon-based direct band gap light-emitting material having a high light-emitting efficiency and a small impurity concentration with a simple manufacturing process. It may provide a brand new solution for on-chip light sources (silicon-based light-emitting devices, that is, on-chip light-emitting devices) required for silicon-based or germanium-based optoelectronic integration technology.

It is found that applying a certain tensile stress to the germanium material to stretch its lattices can transform the band structure of germanium from an indirect band gap to a direct band gap and enable light emission from germanium. The concept of the present disclosure is to fill some of lattice interstitial sites of the silicon-based material (germanium or silicon-germanium alloy) with noble gas atoms and/or other atoms with a lower atomic number in a material growth method, such as ion implantation or electrochemical implantation, so as to expand the lattice volume which may produce an equivalent tensile strain, thereby realizing the transformation from indirect band gap to direct band gap for germanium or silicon-germanium alloy. The lattice structure, electronic structure, and optical properties of the light-emitting germanium material epitaxially grown on a silicon microchip are calculated and simulated by using a first-principles density functional theory. The result shows that the method of filling the lattice interstitial sites with external atoms can indeed expand the lattice, thereby achieving the transformation from indirect band gap to direct band gap, and achieving high efficiency direct band gap light-emission for germanium or silicon-germanium alloy. The corresponding band-edge transition matrix element increases from 0 to a value comparable to that of Group III-V direct band gap materials such as InP and GaAs, affirming that highly-efficient light emission is expected in such doping-induced direct band gap silicon-based material. Therefore, it is theoretically verified that the present disclosure can obtain a CMOS-compatible silicon-based material with a light-emitting efficiency comparable to that of Group III-V direct band gap materials such as InP and GaAs. Based on such a supposition, as long as the concentration of externally implanted atoms is sufficiently high, this method can also enable a silicon-germanium alloy, with a silicon composition no more than 50%, epitaxially grown on a silicon substrate to achieve the direct band gap light-emission. The high efficiency direct band gap light-emitting germanium material or silicon-germanium alloy material prepared by this method can be monolithically and epitaxially grown on a silicon or germanium substrate in high quality in order to fabricate on-chip light sources integrated into silicon microchip or a germanium microchip. Compared with the existing hybrid integration of direct band gap Group III-V materials on top of silicon microelectronics chips, this method can achieve a monolithic epitaxial growth on a silicon substrate, which has a perfect compatibility with current microelectronic CMOS process without the problem of mismatches in thermal expansion and polar/nonpolar, and can be used to large-scale integration of light sources on a microchip. Compared with the existing method of the incorporation of extreme large tin atoms into the germanium material for the direct band gap light-emitting germanium-tin alloy, the present disclosure can significantly reduce the introduction of harmful impurities and lattice defects, thereby obtaining a high-efficiency light-emitting germanium material with more stable properties. This advantage is due to the external atoms implanted in the germanium lattices of the present disclosure having a low atomic number and thus a high solid solubility, and the required concentration of implanted atoms being low. Compared with the existing method of achieving direct band gap light-emission of germanium under tensile strain induced by micromechanical methods, the present disclosure fills some of interstitial sites of the germanium lattices with external atoms to expand the lattice volume, so as to produce an equivalent tensile strain to achieve direct band gap light emission of germanium material. This approach solves the problem that the micromechanical methods cannot be applied for large-scale integration on microchip. Besides, silicon-germanium alloy with low concentration in silicon has similar properties as the germanium material, and thus can also be used to obtain a silicon-based direct band gap light-emitting material.

The method according to the present disclosure is compatible with existing CMOS fabrication process and thus can be used to for large-scale integration of high performance light-emitting devices on silicon or germanium microchips. In addition, with different types and concentrations of atoms to be filled with, the high-efficiency direct band gap light-emitting germanium material or silicon-germanium alloy material of the present disclosure may have different sizes in band gap, and vary in corresponding exciton radiative lifetimes. Hence, the wavelength of the emitted photons can also be tuned in a certain range of far-infrared waveband, thus obtaining high-efficiency light-emitting germanium or silicon-germanium alloy materials with different effects, so as to satisfy different application requirements. In summary, the present disclosure provides a brand new solution for high-efficiency light sources that can be large-scale integrated on a microchip and are key essential for silicon-based or germanium-based optoelectronic integration technology.

In order to make the purpose, technical solution, and advantages more clear, the present disclosure will be further described in detail below in connection with specific embodiments with reference to the accompanying drawings.

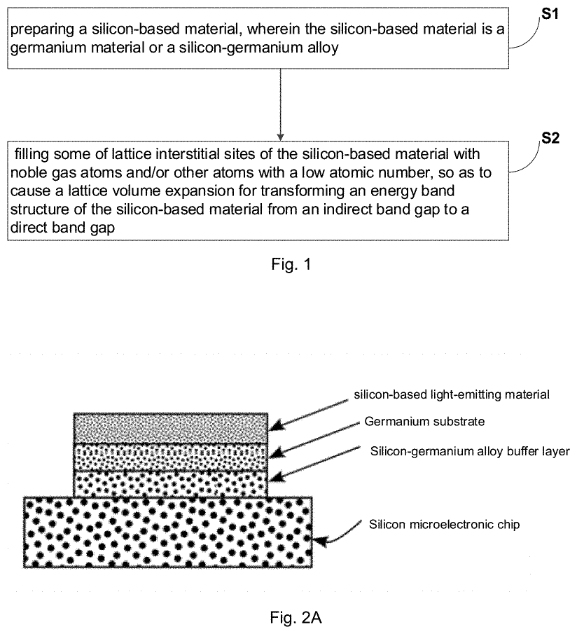

In one aspect of the embodiments of the present disclosure, a method for preparing a silicon-based light-emitting material (a silicon-based direct band gap light-emitting material) is provided. FIG. 1 is a flowchart illustrating steps of a method for preparing a silicon-based light-emitting material according to an embodiment of the present disclosure. The method may comprise the following steps:

S1. Preparing a silicon-based material, wherein the silicon-based material is a germanium material or a silicon-germanium alloy;

The germanium material may be a three-dimensional crystalline structure such as an allotrope of germanium characterized in having a regular tetrahedral bonding. In the embodiments of the present disclosure, a crystalline germanium material with a diamond structure is selected. A bulk material refers to a material with periodic three-dimensional lattices, and also to a thin film material of germanium and a low-dimensional micro/nano structure of germanium. The germanium material is perfectly compatible with mature silicon technology, and is suitable for large-scale integration on silicon microchip in simple preparation and low cost.

Silicon-germanium alloy is formed by a random mixing of silicon and germanium atoms on the diamond lattice, wherein the silicon concentration of the alloy is no more than 50%. In this case, a small amount of silicon is mixed in the germanium material. The energy band structure of such a material can still be changed into the direct band gap by implanting external atoms into interstitial lattice sites, towards a direct band gap light emission with high performance.

S2. Filling some of lattice interstitial sites of the germanium or the silicon-germanium alloy with noble gas atoms and/or other atoms with a low atomic number, so as to expand the lattice volume for transforming the energy band structure of the material from indirect band gap to direct band gap, thereby obtaining a silicon-based direct band gap light-emitting material, which has a light-emitting efficiency comparable to direct band gap Group III-V materials, such as InP and GaAs.

Because the atoms of noble gas (insert gas or rare gas) have full valence electron shells, the interaction with valence electrons of germanium is expected to be absent. Filling some of lattice interstitial sites of the germanium material with noble gas atoms will not change its Fermi level. The influence of filled noble gas atoms on the band structure of the germanium material is in the induced lattice volume expansion, which could be considered as an effective tensile strain. The filled noble gas such as helium has an atom concentration of 9.0% or more relative to that of germanium atoms, resulting in the transformation of indirect band gap germanium to direct band gap light emission. In other embodiments, the filled noble gas atoms are not limited to helium atoms, and may also be neon, argon and krypton atoms. The required concentration of neon, argon and krypton atoms relative to germanium atoms are 1.5% or more, 0.8% or more, and 0.8% or more, respectively, in order to archiving the transformation of indirect band gap germanium to direct band gap light emission. In this case, the implantation of noble gas atoms into some of lattice interstitial sites cause lattice volume expansion, and transformation of the band structure from indirect band gap to direct band gap for germanium material. The doped-induced direct band gap germanium has an excellent light-emission property.

For atoms with a low atomic number (say less than 10), including but not limited to lithium and beryllium, they are easy to be implanted into the interstitial sites of the germanium lattices due to their small atom size and high solid solubility. In particular, it has been experimentally found that both silicon and germanium are excellent electrodes materials for lithium batteries. A large number of lithium atoms can be inserted into silicon and germanium by electrochemical methods, resulting their volume expanded by more than 300% as found experimentally. It is found that when more than 3.0% of the germanium lattice interstitial sites are filled with lithium atoms (that is, the number of lithium atoms reaches 3.0% or more of the number of germanium atoms), the band structure of the germanium material transforms from indirect band gap to direct band gap, which causes the germanium material having an excellent light-emitting property. However, because each lithium atom contains a valence electron, the implantation of lithium atoms into lattice interstitial sites may cause the germanium material becoming a heavily doped n-type material with the Fermi level located in the conduction band. In the embodiment of the present disclosure, implanted lithium with an atom concentration of 3.0% or more is preferred. Generally, the lower in the implanted atom concentration, the more stable in the thermodynamic properties of the germanium lattice, the smaller the influence of the external atoms on the electronic structure of the germanium material, and the less the introduced harmful impurities and lattice defects. This corresponds to the optimized high-efficiency direct band gap light-emitting germanium material in this embodiment.

It should be noted that noble gas atoms with a high atomic number, such as argon and krypton atoms, generally cannot mix with other atoms with a very low atomic number to fill lattice interstitial sites of the silicon-based material, whereas, noble gas atoms with a low atomic number, such as helium and neon atoms, can mix with other atoms with a low atomic number to fill lattice interstitial sites of the silicon-based material. For similar reasons, different types of atoms with low atomic number can also mix with each other, so as to fill some of interstitial sites of the silicon-based material, thereby obtaining a silicon-based direct band gap light-emitting material.

In addition, implanting external atoms into the lattice interstitial sites of the silicon-based material may be realized by using a semiconductor doping process such as ion implantation or electrochemical implantation, or during the epitaxial growth process. In the embodiment of the present disclosure, the ion implantation is adopted, that is, by using an ion implanter to accelerate lithium or helium atoms through an electric field in a vacuum so as to obtain an energetic lithium or helium ion beam to implant into the germanium wafer. A magnetic field is used to regulate the direction of energetic ion beam and then to select ions with a specific energy and fluency for implantation. An annealing process is followed to reduce the concentration of ion-implantation-induced defects. An implantation layer with high light-emitting efficiency is finally formed on the top of the silicon-based material surface. Compared with the conventional diffusion method for doping, the ion implantation method has the advantages such as low processing temperature, uniform implantation over a large area, and easy control of the implantation concentration and depth.

It is important that in different embodiments, the size of the band gap of the silicon-based light-emitting material varies with the type and concentration of implanted atoms, thus, the wavelength of the emitted light from the corresponding band-edge exciton emission can be tuned within a certain range of the far infrared band wave, thereby obtaining silicon-based light-emitting materials with different optical properties, so as to satisfy different application requirements.

In another aspect of the present disclosure, a silicon-based light-emitting material is also provided. The silicon-based light-emitting material is a germanium material or a silicon-germanium alloy with a direct band gap, wherein some of lattice interstitial sites thereof are filled with noble gas atoms and/or other atoms with a low atomic number.

The silicon-based light-emitting material may have a germanium allotrope crystalline structure characterized in a regular tetrahedral bonding. In the embodiments of the present disclosure, the bulk germanium material with a diamond structure is selected. The selected germanium bulk material has periodic three-dimensional lattices, and can also be a thin film and low-dimensional micro/nano structure thereof. The germanium material is suitable for large-scale integration on silicon microchip using mature silicon technology in simple preparation and low cost. In addition, the silicon-based light-emitting material has a light-emitting efficiency comparable to direct band gap Group III-V light-emitting materials such as InP and GaAs, and thus has a direct band gap with high light-emitting efficiency.

A silicon-germanium alloy may also be selected, that is, a random mixing of silicon material and germanium material, wherein the silicon concentration is no more than 50%. In this case, a small amount of silicon is mixed into the germanium material. The band structure of such a material can still be transformed from indirect band gap to direct band gap by implanting external atoms, thereby emitting light efficiently.

The interaction between the electrons of the noble gas atoms and the valence electrons of germanium is expected to be neglected. When the noble gas atoms are implanted in the lattice interstitial sites of the germanium material, it may cause the lattice volume expansion of the germanium material, and generate equivalently a tensile strain, which transforms the band structure of the germanium material from indirect band gap to direct band gap. Such direct band gap germanium material has a property of light-emission with a high efficiency. In the embodiment of the present disclosure, helium atom is selected, and the atom concentration of helium is 9.0% or more. In other embodiments, the filled noble gas atoms are not limited to helium atoms, but may also be neon, argon, and krypton atoms. The concentrations of respective noble gas atoms relative to the germanium atoms are sequentially 1.5% or more, 0.8% or more, and 0.8% or more, sequentially. In this case, due to the implantation of the noble gas atoms, the silicon-based material has a lattice volume expansion and a transformation of its band structure from indirect band gap to direct band gap, thereby possessing an excellent direct band gap light-emitting property.

For atoms with a low atomic number, such as atoms with an atomic number less than 10, including but not limited to lithium and beryllium, they are easy to be implanted into the interstitial sites of the germanium lattices due to their small atom size and high solid solubility. Especially for lithium atoms, the process of implanting large doses of lithium atoms into silicon and germanium by electrochemical methods has been widely used in the industry of lithium batteries. When the number of lithium atoms implanted into interstitial sites of the germanium lattices exceeds 3.0% relative to the germanium atoms, the band structure of the germanium material transforms from indirect band gap to direct band gap, thereby owing an excellent light-emitting property. Generally, the lower the external atom concentration, the more stable the thermodynamic properties of the germanium lattice, the smaller the influence of the external atoms on the band-edge electronic structure of the germanium material, the less in the introduction of harmful impurities and lattice defects. This corresponds to the optimized light-emitting germanium material in this embodiment.

In another aspect of the embodiments of the present disclosure, a silicon-based light-emitting device is also provided. FIG. 2A shows a schematic structural diagram of a silicon-based light-emitting device according to the first embodiment of the present disclosure. As shown in FIG. 2A, the silicon-based light-emitting device comprises: a silicon microelectronic chip; a silicon-germanium alloy buffer layer epitaxially grown on top of the silicon microelectronic chip; a germanium substrate epitaxially grown on top of the silicon-germanium alloy buffer layer; and a silicon-based light-emitting material epitaxially grown on top of the germanium substrate, which is epitaxially grown the silicon microelectronic chip through a silicon-germanium alloy buffer layer. The silicon-based light-emitting material has an induced direct band gap due to some of lattice interstitial sites thereof being filled with noble gas atoms and/or other atoms with a low atomic number.

FIG. 2B shows a schematic structural diagram of a silicon-based light-emitting device according to a second embodiment of the present disclosure. As shown in FIG. 2B, the silicon-based light-emitting device comprises: a germanium microelectronic chip; and a silicon-based light-emitting material epitaxially grown on top of the germanium microelectronic chip. The silicon-based light-emitting material is a direct band gap material having a band structure of direct band gap, wherein some of lattice interstitial sites thereof being filled with noble gas atoms and/or other atoms with a low atomic number.

That is, the silicon-based light-emitting material and hence light-emitters can be monolithically integrated on a germanium or silicon microchip. In the embodiment of the present disclosure, a microelectronic chip is used. By using the above-mentioned silicon-based light-emitting material compatible with the CMOS fabrication process, both photonic devices and electronic devices are integrated on a single chip, thereby realizing a large-scale integrated optoelectronic chip. This may enable a full exploitation of the properties of the electronic devices and photonic devices, a great improvement on the computing capability of a single chip, a significant decrease of power consumption and heat generation of the system, a resolution of functions and performance in computing, communications, and sensing.

The method for depositing, on top of the microelectronic chip, the silicon-germanium alloy buffer layer, the germanium substrate, and the light-emitting germanium material may be one or more of approaches including atomic layer deposition, plasma enhanced chemical vapor deposition, magnetron sputtering, molecular beam epitaxy or metal organic chemical vapor deposition, dry oxidation, wet oxidation, and ion implantation.

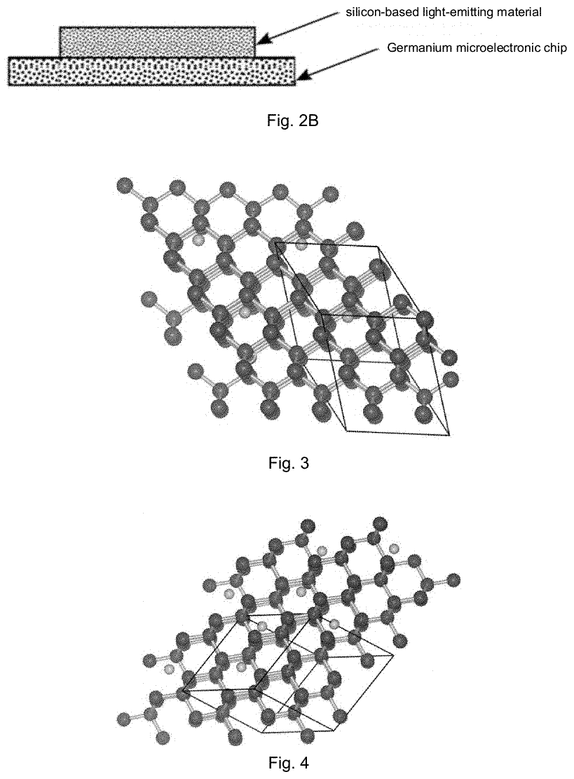

FIG. 3 is a schematic diagram of a crystalline structure for germanium containing 3.0% lithium atom (Ge₃₂Li₁) according to an embodiment of the present disclosure. In a supercell of 32 germanium atoms, one lithium atom is filled randomly in one of the interstitial sites of the germanium lattices. FIG. 4 is a schematic diagram of a crystalline structure for germanium containing 6% lithium atoms (Ge₃₂Li₂) according to an embodiment of the present disclosure. In a supercell of 32 germanium atoms, two lithium atoms are filled in two of the interstitial sites of the germanium lattices according to the special quasi-random structures (SQS). As shown in FIG. 3 and FIG. 4, in a case of Ge₃₂Li₁ for 3.0% Li concentration, the lattice constant predicted by the first-principle density functional theory calculation is 5.689 Å; in a case of Ge₃₂Li₂ for 6.0% Li concentration, the predicted lattice constant is 5.723 Å.

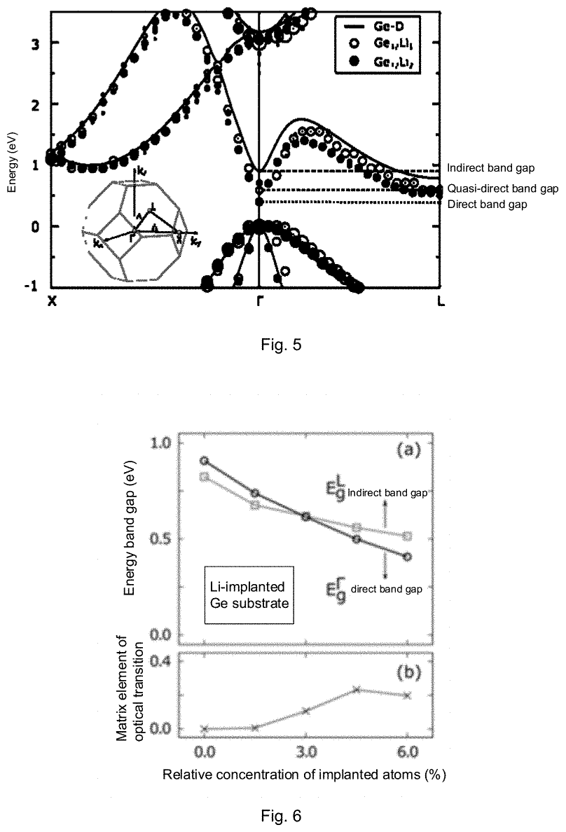

FIG. 5 is a schematic diagram for effective band structures of 3.0% lithium doped germanium crystalline structure (Ge₃₂Li₁) and the 6.0% lithium doped germanium crystalline structure (Ge₃₂Li₂) by projecting their electronic states on a pure germanium FCC Brillouin zone according to the embodiment of the present disclosure. The dots or circles as shown in FIG. 5 represent the pure germanium Bloch states with energy given by the parental electronic states of Ge₃₂Li₁ or Ge₃₂Li₂, respectively, and their size represents the component of the corresponding pure germanium Bloch state in the parental electronic states, obtained from the projection. By comparing the band structures of pure germanium crystal, 3.0% lithium doped germanium material Ge₃₂Li₁, and 6.0% lithium doped germanium material Ge₃₂Li₂, it can be seen that, although the pure germanium crystal is an indirect band gap material, 6.0% lithium doped germanium material becomes a direct band gap material, and the 3.0% lithium doped germanium material has almost equal energy levels between direct band gap and indirect band gap, and thus is the transition point from indirect band gap to direct band gap for lithium concentration. If the energy level of the direct band gap is lower than the energy level of the indirect band gap, this material has a direct band gap and excellent light-emitting property. Otherwise, material has an indirect band gap and a poor light-emitting property with its intensity 2-5 orders weaker than that of the direct band gap materials such as GaAs and InP, and thus not suitable for serving as a light-emitting material. It is noted that from the pure germanium material through 3.0% lithium doped germanium material to 6.0% lithium doped germanium material, the energy level of the direct band gap decreases faster than that of the indirect band gap and being higher, same, and lower than that of the indirect band gap, respectively.

FIG. 6 is a schematic diagram illustrating the energy levels of the direct and indirect band gaps, and the band-edge transition matrix element against the lithium concentration for lithium doped germanium material, which is assumed epitaxially grown on the germanium substrate according to an embodiment of the present disclosure. Since the germanium material undergoes a volume expansion after the lithium atoms are implanted into interstitial sites, the germanium substrate restricts the lithium doped germanium material to have the same planar lattice as pure germanium, and allows only the vertical lattice to expand. In addition, the germanium substrate can be a monocrystal germanium wafer, or a strain-free monocrystal germanium layer obtained by epitaxially growing a silicon-germanium alloy buffer layer on top of the silicon substrate. As shown in FIG. 6(a), when the concentration of doped lithium atoms in germanium material reaches 3.0% or more, the energy level of the direct band gap is lower than that of the indirect band gap, and thus the band structure thereof is transformed from indirect band gap to direct band gap. The lithium doped germanium material with a above-mentioned threshold concentration has a direct band gap of 0.61 eV. As shown in FIG. 6(b), accompanying the transformation of the band structure from indirect band gap to direct band gap, the corresponding matrix element of the band-edge optical transition undergoes a transition from zero to 0.20 a.u. occurred nearby the lithium concentration of 3.0%. Considering that the band-edge transition matrix element of direct band gap Group III-V materials such as GaAs and InP are around 0.3 a.u., it is concluded that the light-emitting germanium material according to the embodiment of the present disclosure is a high-efficiency light-emitting material with a direct band gap.

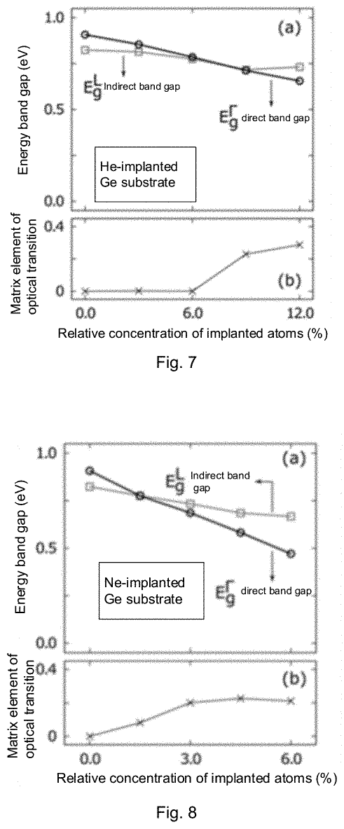

FIG. 7 is a schematic diagram illustrating the energy levels of the direct and indirect band gaps, and the band-edge transition matrix element against the helium concentration for helium doped germanium material, which is assumed epitaxially grown on the germanium substrate according to an embodiment of the present disclosure. Since the germanium material undergoes a volume expansion after the helium atoms are implanted into interstitial sites, the germanium substrate restricts the helium doped germanium material to have the same planar lattice as pure germanium, and allows only the vertical lattice to expand. In addition, the germanium substrate can be a monocrystal germanium wafer, or a strain-free monocrystal germanium layer obtained by epitaxially growing a silicon-germanium alloy buffer layer on top of the silicon substrate. As shown in FIG. 7(a), when the concentration of doped helium atoms in germanium material reaches 9.0% or more, the energy level of the direct band gap is lower than that of the indirect band gap, and thus the band structure thereof is transformed from indirect band gap to direct band gap. The helium doped germanium material with the above-mentioned threshold concentration has a direct band gap of 0.71 eV. As shown in FIG. 7(b), accompanying the transformation of the band structure from indirect band gap to direct band gap, the corresponding matrix element of the band-edge optical transition undergoes a transition from zero to 0.22 a.u. occurred nearby the helium concentration of 9.0%. Considering that the band-edge transition matrix element of direct band gap Group III-V materials such as GaAs and InP are around 0.3 a.u., it is concluded that the light-emitting helium doped germanium material according to the embodiment of the present disclosure is a high-efficiency light-emitting material with a direct band gap.

FIG. 8 is a schematic diagram illustrating the energy levels of the direct and indirect band gaps, and the band-edge transition matrix element against the neon concentration for neon doped germanium material, which is assumed epitaxially grown on the germanium substrate according to an embodiment of the present disclosure. Since the germanium material undergoes a volume expansion after the neon atoms are implanted into interstitial sites, the germanium substrate restricts the neon doped germanium material to have the same planar lattice as pure germanium, and allows only the vertical lattice to expand. In addition, the germanium substrate can be a monocrystal germanium wafer, or a strain-free monocrystal germanium layer obtained by epitaxially growing a silicon-germanium alloy buffer layer on top of the silicon substrate. As shown in FIG. 8(a), when the concentration of doped neon atoms in germanium material reaches 1.5% or more, the energy level of the direct band gap is lower than that of the indirect band gap, and thus the band structure thereof is transformed from indirect band gap to direct band gap. The neon doped germanium material with a above-mentioned threshold concentration has a direct band gap of 0.78 eV. As shown in FIG. 8(b), accompanying the transformation of the band structure from indirect band gap to direct band gap, the corresponding matrix element of the band-edge optical transition undergoes a transition from zero to 0.10 a.u. occurred nearby the neon concentration of 1.5%. Considering that the band-edge transition matrix element of direct band gap Group III-V materials such as GaAs and InP are around 0.3 a.u., it is concluded that the light-emitting neon doped germanium material according to the embodiment of the present disclosure is a high-efficiency light-emitting material with a direct band gap.

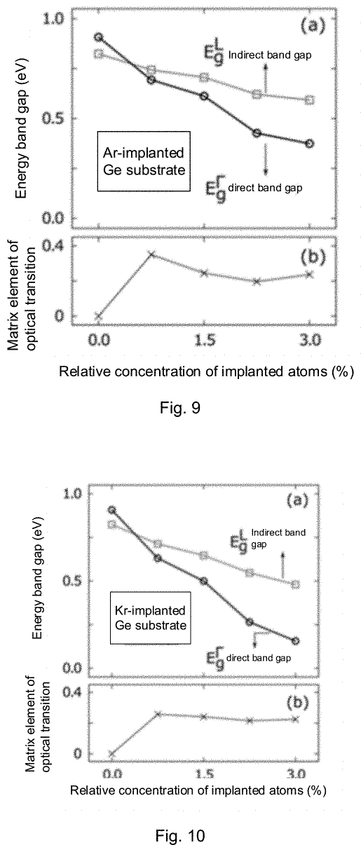

FIG. 9 is a schematic diagram illustrating the energy levels of the direct and indirect band gaps, and the band-edge transition matrix element against the argon concentration for argon doped germanium material, which is assumed epitaxially grown on the germanium substrate according to an embodiment of the present disclosure. Since the germanium material undergoes a volume expansion after the argon atoms are implanted into interstitial sites, the germanium substrate restricts the argon doped germanium material to have the same planar lattice as pure germanium, and allows only the vertical lattice to expand. In addition, the germanium substrate can be a monocrystal germanium wafer, or a strain-free monocrystal germanium layer obtained by epitaxially growing a silicon-germanium alloy buffer layer on top of the silicon substrate. As shown in FIG. 9(a), when the concentration of doped argon atoms in germanium material reaches 1.5% or more, the energy level of the direct band gap is lower than that of the indirect band gap, and thus the band structure thereof is transformed from indirect band gap to direct band gap. The argon doped germanium material with a above-mentioned threshold concentration has a direct band gap of 0.78 eV. As shown in FIG. 9(b), accompanying the transformation of the band structure from indirect band gap to direct band gap, the corresponding matrix element of the band-edge optical transition undergoes a transition from zero to 0.36 a.u. occurred nearby the argon concentration of 1.5%. Considering that the band-edge transition matrix element of direct band gap Group III-V materials such as GaAs and InP are around 0.3 a.u., it is concluded that the light-emitting argon doped germanium material according to the embodiment of the present disclosure is a high-efficiency light-emitting material with a direct band gap.

FIG. 10 is a schematic diagram illustrating the energy levels of the direct and indirect band gaps, and the band-edge transition matrix element against the krypton concentration for krypton doped germanium material, which is assumed epitaxially grown on the germanium substrate according to an embodiment of the present disclosure. Since the germanium material undergoes a volume expansion after the krypton atoms are implanted into interstitial sites, the germanium substrate restricts the krypton doped germanium material to have the same planar lattice as pure germanium, and allows only the vertical lattice to expand. In addition, the germanium substrate can be a monocrystal germanium wafer, or a strain-free monocrystal germanium layer obtained by epitaxially growing a silicon-germanium alloy buffer layer on top of the silicon substrate. As shown in FIG. 10(a), when the concentration of doped krypton atoms in germanium material reaches 0.8% or more, the energy level of the direct band gap is lower than that of the indirect band gap, and thus the band structure thereof is transformed from indirect band gap to direct band gap. The krypton doped germanium material with a above-mentioned threshold concentration has a direct band gap of 0.63 eV. As shown in FIG. 10(b), accompanying the transformation of the band structure from indirect band gap to direct band gap, the corresponding matrix element of the band-edge optical transition undergoes a transition from zero to 0.28 a.u. occurred nearby the krypton concentration of 0.8%. Considering that the band-edge transition matrix element of direct band gap Group III-V materials such as GaAs and InP are around 0.3 a.u., it is concluded that the light-emitting krypton doped germanium material according to the embodiment of the present disclosure is a high-efficiency light-emitting material with a direct band gap.

The specific embodiments of the present disclosure have been described in detail, and are not intended to limit the present invention. Any modifications, equivalent substitutions, improvements, etc., made within the spirit and scope of the present invention, are intended to be included within the scope of the present invention.

1. A method for preparing a silicon-based direct band gap light-emitting material, compatible with the CMOS fabrication process, comprising:
S1. preparing a silicon-based material, wherein the silicon-based material is a germanium material or a silicon-germanium alloy;
S2. filling some of lattice interstitial sites of the silicon-based material with noble gas atoms and/or other atoms with a low atomic number, so as to cause a lattice volume expansion for transforming an energy band structure of the silicon-based material from an indirect band gap to a direct band gap, thereby obtaining a silicon-based direct band gap light-emitting material.

2. The method of claim 1, wherein filling is implemented by ion implantation, electrochemical implantation, and epitaxial growth.

3. The method of claim 1, wherein a concentration of silicon in the silicon-germanium alloy is no more than 50%.

4. A silicon-based light-emitting material, wherein the silicon-based light-emitting material is a germanium material or a silicon-germanium alloy having a band structure of direct band gap, wherein some of lattice interstitial sites thereof are filled with noble gas atoms and/or other atoms with a low atomic number.

5. The silicon-based light-emitting material of claim 4, wherein the silicon-based light-emitting material is a crystalline structure characterized in having a regular tetrahedral bonding.

6. The silicon-based light-emitting material of claim 5, wherein the crystalline structure characterized in having the regular tetrahedral bonding is a diamond structure or a biaxially strained diamond-like structure.

7. The silicon-based light-emitting material of claim 4, wherein the silicon-based light-emitting material is a bulk material, a thin film material, or a micro/nano structure material.

8. The silicon-based light-emitting material of claim 4, wherein the noble gas atoms are helium atoms with a concentration of 9.0% or more relative to the germanium atoms; and/or
the noble gas atoms are neon atoms with a concentration of 1.5% or more relative to the germanium atoms; and/or
the noble gas atoms are argon atoms with a concentration of 0.8% or more relative to the germanium atoms; and/or
the noble gas atoms are krypton atoms with a concentration of 0.8% or more relative to the germanium atoms.

9. The silicon-based light-emitting material of claim 4, wherein the other atoms with a low atomic number comprises lithium atoms with a concentration of 3.0% or more relative to the germanium atoms.

10. A silicon-based light-emitting device, comprising:
a microelectronic chip, comprising a silicon microelectronic chip or a germanium microelectronic chip;
a silicon-germanium alloy buffer layer, disposed on top of the silicon microelectronic chip;
a germanium substrate, disposed on top of the silicon-germanium alloy buffer layer; and
a silicon-based light-emitting material, disposed on top of the germanium substrate or directly on the germanium microelectronic chip, the silicon-based light-emitting material being a germanium material or a silicon-germanium alloy having an band structure of direct band gap, wherein some of lattice interstitial sites thereof are filled with noble gas atoms and/or other atoms with a low atomic number.
